(19) United States
(12) Patent Application Publication
(10) Pub. No.: US 2010/0252085 A1
(43) Pub. Date: Oct. 7, 2010

(54) PORTABLE DIRECT SOLAR THERMOELECTRIC GENERATOR

(75) Inventors: John Gotthold, Sunnyvale, CA (US); Anjun Jerry Jin, Palo Alto, CA (US); Frank M. Larsen, Gilroy, CA (US)

Correspondence Address: Dr. Anjun Jerry Jin, 2096 Ascot Driver, Apt. 10, Moraga, CA, 94556, US

(73) Assignee: Hoda Globe Corporation, San Jose, CA (US)

(21) Appl. No.: 12/535,574

(22) Filed: Aug. 4, 2009

Related U.S. Application Data
(60) Provisional application No. 61/197,576, filed on Oct. 29, 2008.

(51) Int. Cl. H01L 35/00

(52) U.S. Cl. 136/206

(57) ABSTRACT

Various methods and apparatuses are described for a portable electric generator powered by a solar thermal electric power source. The device can transform from a compact tote-able configuration into a fully operational high power direct thermo electric generator in a matter of minutes. The portable electric generator powered by a solar thermal electric power source utilizes a folding mount, a sectional rotationally folding parabolic dish and a chimney air-cooled direct thermoelectric generator power head.

### RELATED APPLICATIONS

This application claims benefit of U.S. provisional patent application No. 61/197,576, titled ‘PORTABLE DIRECT SOLAR THERMAL ELECTRIC GENERATOR’ filed Oct. 29, 2008.

### FIELD

The present invention relates to the field of portable power generation and in one aspect using thermal electric devices, referred to as solar thermal electricity generators.

### BACKGROUND

In the past, portable electric generators have primarily been of the gasoline engine driving and electric generator type. The drawbacks to this form of prior art have been the weight of the device and the noise, exhaust fumes and vibrations of its use. Additionally, the gasoline fuel had to be toted along with the device and the overall efficiency was low requiring return trips to replenish said fuel. More recently, small amounts of portable electric power have been produced through flexible solar photovoltaic panels, such as for keeping a charge on boat batteries when the boat was idle. However, since the solar to electric conversion efficiency was low, in the range of six to eight percent, the flexible solar panels required a large area and heavy package to tote sufficient flexible solar panels to generate sufficient electricity.

Further back in history, devices known as thermoelectric piles were created. These devices utilized direct thermal to electric conversion means, but at a very low thermal to electric conversion efficiency, in the range of two to four percent. These thermoelectric piles were supplied heat by burning fossil fuel, coal, oil, or natural gas, and later propane and butane were utilized. However, the combustion of fossil fuel always resulted in the release of pollution, requiring a dispersal means, such as a chimney. Additionally trips to replenish the stocks of fossil fuel were required. The exceedingly low thermal to electric conversion efficiency of said thermoelectric piles limited their use to primarily fixed locations.

### SUMMARY

A portable electric generator powered by a solar thermal electric power source may be composed of three or more sections of mechanical and thermal mechanical devices. The sections are the collapsible base mount, rotate-ably fold-able parabolic reflector section and the direct solar thermal to electric generator (STEG) head section housing a thermally cascading stack of multiple thermal electric cores. The three sections are fold-ably and electrically connected and the device can be folded for transport or erected to begin thermoelectric generation (TEG) in a matter of minutes.

### BRIEF DESCRIPTION OF THE DRAWINGS

FIG. 1 illustrates an embodiment of the collapsible base mount.

FIG. 2. illustrates an embodiment of the collapsible base mount folded into its collapsed form.

FIG. 3. illustrates an embodiment of the rotate-ably foldable parabolic reflector section.

FIG. 4. illustrates an embodiment of the rotate-ably foldable parabolic reflector section in the folded condition.

FIG. 5. illustrates an embodiment of the solar direct thermal to electric converter head section support.

FIG. 6. illustrates an embodiment of a thermally cascading stack of multiple thermal electric cores in the thermal electric generation device.

FIG. 7. illustrates an embodiment of the thermal to electric converter head section.

FIG. 8. illustrates an embodiment of the thermal to electric converter head section and its thermal dissipater to transfer thermal energy to the atmospheric air.

FIG. 9 illustrates the combination of said inner solar thermal section, said outer thermal dissipation section and said solar direct thermal to electric converter head section support.

FIG. 10 illustrates an embodiment of said solar direct thermal electric generator in its erected and generating state.

FIG. 11 illustrates an embodiment of said solar direct thermal electric generator in its folded, transportable form.

FIG. 12 illustrates an embodiment of said solar direct thermal electric generator with an attached DC to AC converter (41) module enabling said solar direct thermal electric generator to provide both DC current and AC current as long as the sun is shining.

FIG. 13 illustrates said thermal throttle comprised of alternating parts of the three sections in upper and lower two bodies that may slide in side from each other by offsetting certain distance.

While the invention is subject to various modifications and alternative forms, specific embodiments thereof have been shown by way of example in the drawings and will herein be described in detail. The invention should be understood to not be limited to the particular forms disclosed, but on the contrary, the intention is to cover all modifications, equivalents, and alternatives falling within the spirit and scope of the invention.

### DETAILED DISCUSSION

In the following description, numerous specific details are set forth, such as examples of specific data signals, named components, connections, number of thermal electric cores, etc., in order to provide a thorough understanding of the present invention. It will be apparent, however, to one of ordinary skill in the art that the present invention may be practiced without these specific details. In other instances, well known components or methods have not been described in detail but rather in a block diagram in order to avoid unnecessarily obscuring the present invention. Further specific numeric references, such as first core, may be made. However, the specific numeric reference should not be interpreted as a literal sequential order but rather interpreted that the first core is different than a second core. Thus, the specific details set forth are merely exemplary. The specific details may be varied from and still be contemplated to be within the spirit and scope of the present invention. The term coupled is defined as meaning connected either directly to the component or indirectly to the component through another component.

In general, a portable electric generator powered by a solar thermal electric power source is discussed. The parabolic solar dish is configured to collect and reflectively concentrate solar photon energy into a heat-containment housing that contains some black body heat absorber to trap heat energy from the solar photon energy and that manages a thermal energy flow into a thermal electric generation device. A thermally cascading stack of multiple thermal electric cores is contained in the thermal electric generation device. Each of the thermal electric cores may be composed of pairs of P-type and N-type materials optimized for the thermal electric generation in specific temperature ranges and exhibit the thermal electric effect at progressively lower temperatures. Power bus bars couple to the thermal electric generation device. A collapsible base mount has a hollow tube for a vertical support and connects to the parabolic solar dish to structurally support the parabolic solar dish. The three sections 1) the collapsible base mount, 2) the parabolic solar dish, and 3) the thermally cascading stack of multiple thermal electric cores are fold-ably and electrically connected and the device can be folded for transport [or erected to begin thermoelectric generation (TEG) in a matter of minutes.

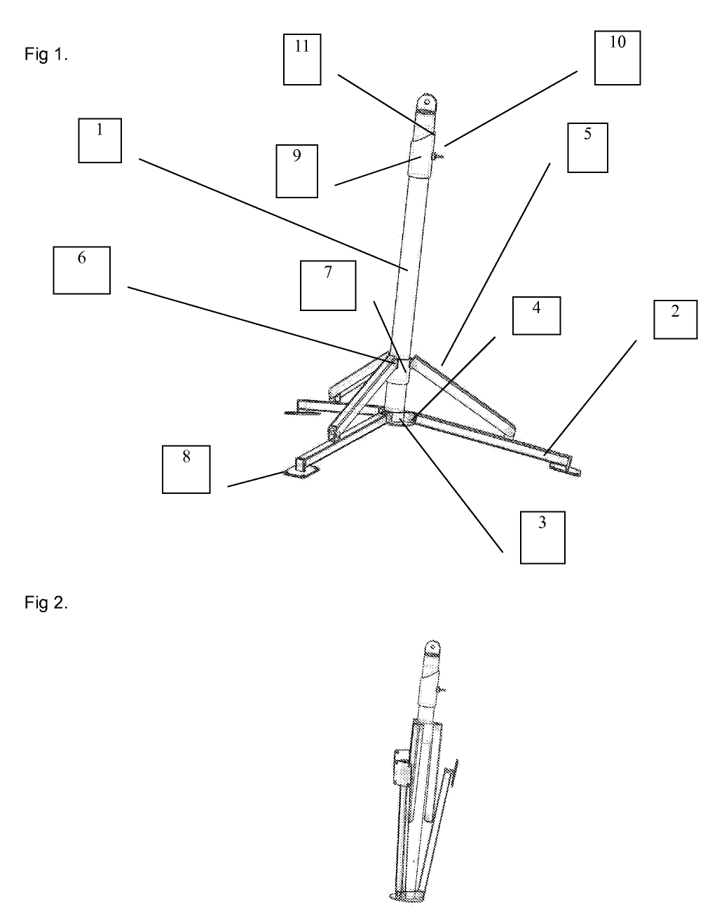

Referring to FIG. 1.

FIG. 1 illustrates an embodiment of the collapsible base mount. Said collapsible base mount is composed of a hollow tube (1) of cylindrical, square or any other geometric shape, a multiple more than two of support legs (2) (three in the preferred embodiment). The bottom of said hollow tube is fixedly fastened to a base collar (3) and said support legs (2) are rotationally attached to said base collar (3) by through pins (4) such that said support legs (2) can fold to a position parallel to said hollow tube (1). Attached to said support legs (2) are one for one, support braces (5) and said support braces (5) are rotationally attached to said support legs (2) such that said support braces (5) can fold into a position at an angle up to parallel relative to said support legs(2). The second end of said support braces (5) are rotate-ably attached to a slide locking collar (6), which surrounds said hollow tube (1) and can slid up and down its length.

Referring to FIG. 1. (cont.)

The second end of said support braces are flexibly angularly attached to said slide locking collar (6) by additional thru pins (4). The collapsible base mount has a locking collar (6) that has an integral detent-locking pin (7) or pins, such that said slide locking collar (6) can be slid up and down said hollow tube (1), in turn angularly altering the position of said support braces (5) and said support legs (2) such that said collapsible base mount can be mounted upon nearly any surface. The collapsible base mount has stable support due to the adaptable shape of the support legs (2), which can, for example, be positioned low and wide to resist falling over on windy days. Fixedly attached to the end of said support legs (2) are mounting feet (8) which spread the force of said support legs (2) and allow said collapsible base mount to be mounted either on hard or soft soil. Slideably mounted on said hollow tube (1) is a sliding angle collar (9) which can be slid up and rotated around the circumference of the hollow tube (1) of the collapsible base mount and then fastened into place by wing nut (10) to position the second section at an optimum angle and rotation of the Sun. Attached to the top of said hollow tube (1) is a pivot bracket (11) which acts as the angularly variable attachment point for the parabolic solar dish and an extension tube. Devices such as the above have been utilized for such tasks as being the mounting base for portable projector screens, photographic camera tripods, etc.

FIG. 2. illustrates an embodiment of the collapsible base mount folded into its collapsed form. Referring to FIG. 2, the collapsible base mount described above and illustrated in FIG. 1. can be folded into its collapsed form as illustrated in FIG. 2.

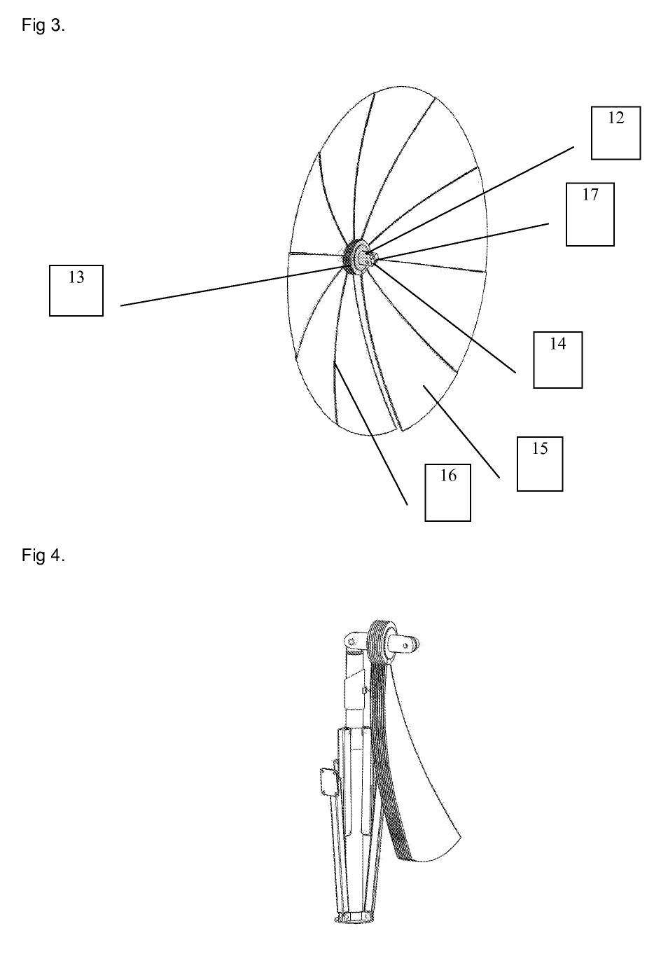

FIG. 3. illustrates an embodiment of the rotate-ably foldable parabolic reflector section.

Referring to FIG. 3, the second section of this disclosure is the rotate-ably foldable parabolic reflector section. FIG. 3. shows a fan tube (12) which mounts a relatively large threaded fitting (13) and has angularly adjustable fittings (14) on both ends of said fan tube (12). Rotate-ably mounted on said large threaded fitting (13) are a multiplicity of sectional parabolic solar reflectors (15). These sectional parabolic solar reflectors (15) are made, in the preferred embodiment, of aluminum or any other material which can exhibit a highly solar reflective parabola focused surface, such as molded plastic coated with a reflective coating, of types and designs well known to those skilled in the art. These sectional parabolic solar reflectors (15) have holes in their attachment ends, formed in such a way as to allow said sectional parabolic solar reflectors (15) to rotate in the spiral groove of said large threaded fitting (13). Said sectional parabolic solar reflectors (15) have folded edges (16) which interlock with each other when the sectional parabolic solar reflectors (15) are rotated so as to create a full circular parabolic shape. In the preferred embodiment, there are eight of said sectional parabolic solar reflectors (15), but there can be any number of them, the trade off being mechanical complexity relative to smaller individual section size. At both ends of said fan tube (12) said angularly adjustable fittings (14) are attached to support tubes from sections one and three by rotatable axis centered pins (17).

Thus, the portable electric generator has a parabolic solar dish that includes a multiplicity of sectional parabolic solar reflectors (15) having holes in their attachment ends, formed in such a way as to allow the sectional parabolic solar reflectors (15) to rotate in the spiral groove of a large threaded fitting (13) on the collapsible base mount. The sectional parabolic solar reflectors (15) also have folded edges (16) which interlock with each other when the sectional parabolic solar reflectors (15) are rotated so as to create a full circular parabolic shape.

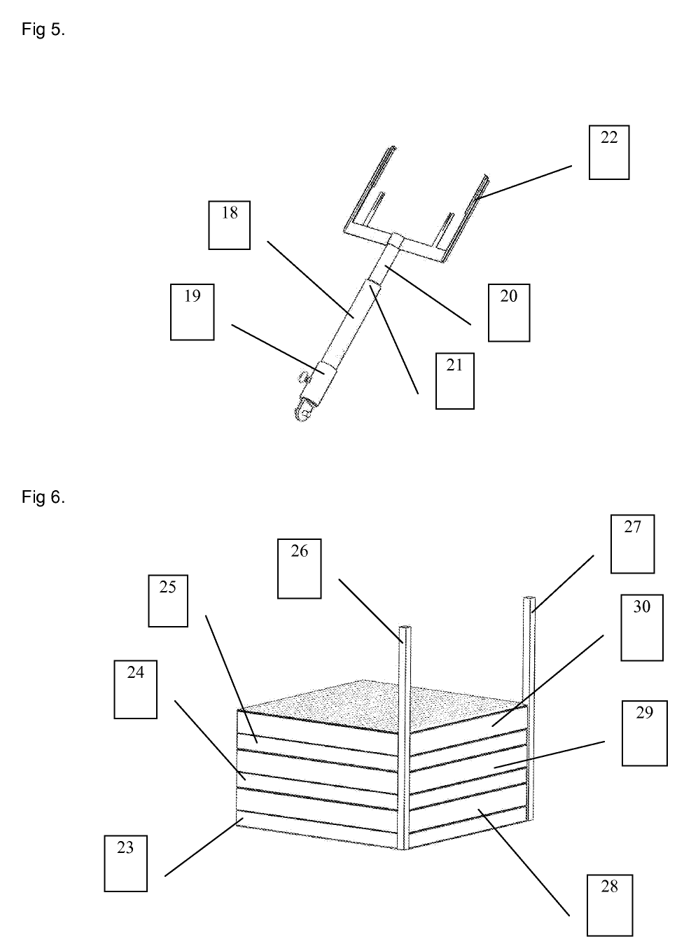

FIG. 4. illustrates an embodiment of the rotate-ably foldable parabolic reflector section in the folded condition.

Referring FIG. 4, the parabolic solar dish is rotate-ably connected to the collapsible base mount, and has a fold-able parabolic reflector section. The sectional parabolic solar reflectors (15) are rotated such that they have progressed rotate-ably around and along said groove of said large threaded fitting (13) until they are all lined up. Said rotation around and along said groove of said large threaded fitting (13) moves said angularly sectional parabolic solar reflectors (11) along the axis of said large threaded fitting (9) sufficiently such that said folded edges (16) bypass each other. Said collapsible base mount is illustrated in the folded condition and is relatively parallel to the stack of said sectional parabolic solar reflectors (15). Said sliding angle collar (9) has been slid back to allow the relative angular folding and then returned to lock said collapsible base mount relative to said rotate-ably foldable parabolic reflector section.

Thus, the portable electric generator has a parabolic solar dish that includes a multiplicity of sectional parabolic solar reflectors (15) that are shaped to form a parabola when expanded in a folded-out position and are grooved and has folds to interlock at the edges (16) when the sections are rotated to a folded-up position. The parabolic solar dish includes a multiplicity of sectional parabolic solar reflectors (15) that are foldable as a pin-latched fan-fold into alignment one section behind the next section. The multiplicity of sectional parabolic solar reflectors (15) has a parabolic surface that can snap into place to create a full circular parabolic shape. The parabolic solar dish may have some light-weight thin-film materials employed in the parabola to enhance the efficiency in order to collect the solar photon heat energy.

Referring to FIG. 5.

FIG. 5. illustrates an embodiment of the solar direct thermal to electric converter head section support. This section is composed of a head section mounting hollow shaft (18), a head shaft locking collar (19), and an extension tube (20) with fixedly mounted detent pins (21) and a head mount bracket (22).

FIG. 6. illustrates an embodiment of a thermally cascading stack of multiple thermal electric cores in the thermal electric generation device.

Referring to FIG. 6, the multiple core stack has three or more cascading temperature ranges with a different thermal electric material in each thermal electric core 23, 24, 25 selected for an optimal temperature to generate electricity at each particular temperature range. The thermal solar electric generator converts sunlight into electricity in two steps: 1) sunlight energy is converted into heat in a chamber that contains a broadband photon trapper known as the black body absorber; 2) the trapped heat is then converted into electricity through the Thermal Electric Generator cores (23, 24, 25). Each of the cores (23, 24, 25) in the thermally cascading stack is composed of materials optimized to exhibit the thermal electric effect at progressively lower temperatures. This arrangement forces said thermal energy collected by said black body solar energy absorber to first activate the top core in the stack of Thermal Electric Generator cores.

a In an embodiment, the Thermal Electric Generator cores (23, 24, 25) may be HODA multi-stacked Thermal Electric Generator cores, which refer to HODA GLOBE Corporation, U.S. patent applications Ser. No. 12/110,097, titled ‘LARGE SCALE ARRAY OF THERMOELECTRIC DEVICES FOR GENERATION OF ELECTRIC POWER’ filed on Apr. 25, 2008 and Ser. No. 12/229,708, titled ‘MULTI-CORES STACK SOLAR THERMAL ELECTRIC GENERATOR’ filed on Aug. 28, 2008, which are incorporated in by reference into the present application. The Thermal Electric Generator is composed of three of more HODA TE generators (23, 24, 25) which are optimized to operate at their highest thermal to electric conversion efficiency at three different temperature ranges. In FIG. 6 said highest temperature HODA TE (23) composed of materials that allow it to operate optimally at around five hundred degrees Celsius.

As said thermal energy transmits through said HODA high temperature TE (23) sixteen to twenty percent of said thermal energy will be converted into direct current (DC) electrical energy. Said electrical energy is drawn off through positive (26) and negative (27) buss bars, composed of materials well known to those skilled in the art and attached to said HODA high temperature TE (23) by a variety of welding processes of types and means well known to those skilled in the art. Said thermal energy transmits through said HODA high temperature TE (23) and into a thermal throttle (28), composed of a variety of materials and geometries, which regulates the rate of thermal flow into the HODA medium temperature TE (24) which optimally operates at approximately three hundred and eighty degrees Centigrade. Said thermal energy proceeds through said HODA medium temperature TE (24) converting an additional sixteen to twenty percent of said thermal energy into electricity, which is drawn off into said positive (26) and negative (27) buss bars. The remaining thermal energy transmits from said HODA medium temperature TE (24) through a second thermal throttle (29) which is composed of a variety of materials and geometries, which regulates the rate of thermal flow into the HODA low temperature TE, (25) which operates at highest conversion efficiency at approximately one hundred and sixty degrees Centigrade. Again approximately sixteen to twenty percent of said thermal energy is drawn off from said HODA low temperature TE, (25) as DC electricity and into said positive (26) and negative (27) bus bars. Thermally bonded to said HODA low temperature TE, (25) is a third thermal throttle (30) which is composed of a variety of materials and geometries, which regulates the rate of thermal flow through said HODA low temperature TE, (25) to a thermal dissipation means FIG. 6. Said thermal energy flow thus is exposed to said HODA TE generators (23, 24, 25) at their optimum efficiency temperature and each of said generators contributes DC electricity. The sum of said thermal energy to electricity conversion can approach 40 percent.

Thus, each core (23, 24, 25) has a heat receiving surface and a relatively cooler heat delivery surface. The heat receiving surface of the first of the stacked cores is exposed to an elevated temperature heat source. The heat delivery surface of the upper most of the stacked cores is exposed to a relatively cooler temperature such that each of the stacked cores is exposed to a temperature differential with the heat delivery surface of each core transmitting heat to the heat receiving surface of the adjacent core stacked thereon. The individual thermal electric cores (23, 24, 25) are composed of pairs of P-type and N-type materials that are optimized for highest thermal electric efficiency in the following temperature ranges and include but not limited to ones listed below:

900 deg C. P=SiGe

900 deg C. N=SiGe

600 deg C. P=SnTe or CeFe4Sb12

600 deg C. N=CoSb3

500 deg C. P=PbTe or TAGS or (Bix, Sbi-x) Te3

500 deg C. N=PbTe (500 C and below)

380 deg C. P=Zn4Sb3

380 deg C. N=PbTe (500 C and below)

160 deg C. P=Bi2Te3

160 deg C. N=Bi2Te3

The thermal electric cores (23, 24, 25) composed of said P type and N type materials are separated by thermal throttles (28, 29, 30) which maintain a uniform thermal flow such that the thermal electric core materials are maintained close to their optimum efficiency temperature within the stack.

Overall, direct current (DC) electrical energy is drawn off each core stack of paired thermal electric material through positive (26) and negative (27) bus bars to contribute DC electricity to the bus bars to sum an efficiency of the heat energy to electrical generation conversion as each cascaded core stack generates DC electrical energy at progressively lower temperatures. The solar thermal electric generator has multi-stack device architecture to maximize the thermal electric system efficiency by utilizing multiple times of waste heat through thermal management mechanism.

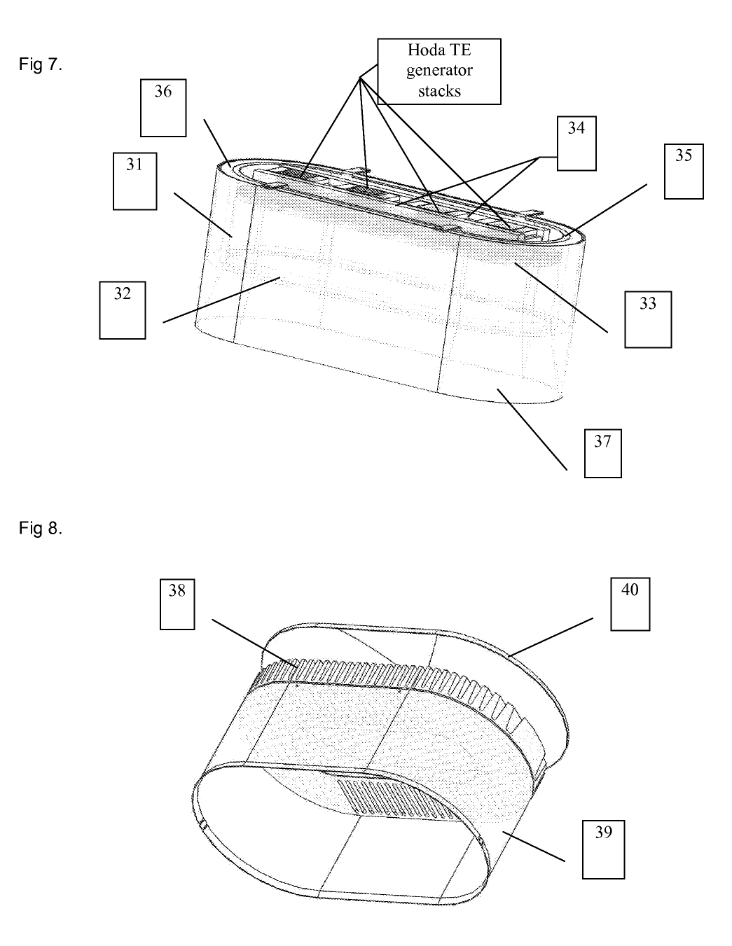

FIG. 7. illustrates an embodiment of the thermal to electric converter head section.

Referring to FIG. 7, the thermal to electric converter head section is comprised of an inner solar thermal section and an outer thermal dissipation section. In FIG. 7, said inner solar thermal section is composed of an obround thin walled tube (31). The geometry of said thin walled tube may be varied from rectangular to obround, depending on design style. Inside the first opening of said obround thin walled tube (31) is a solar thermal trapping window (32). Said window is composed of glass or quartz and coated on the solar energy exposed side with an anti-reflection coating of materials and utilizing processes well known to those skilled in the art. On the non solar energy exposed side said window is coated with thermally reflectively materials and utilizing processes well known to those skilled in the art. This coating combination enhances the normal ability of said solar thermal trapping window (32) to allow said solar thermal energy to pass through said window and then hot allow said solar thermal energy to escape. Said solar thermal trapping window (32) may be shaped in a variety of geometric forms, in the preferred embodiment, in obround form, allowing it to be placed inside said obround thin walled tube (31). Said obround thin walled tube (31) and said solar thermal trapping window (32) are shaped such that focused solar thermal energy reflected from said rotate-ably foldable parabolic reflector section can enter said window for a period of two hours minimum before said rotate-ably foldable parabolic reflector section must be realigned to the sun to maintain said solar thermal energy reflection window entrance. The diameter of the parabolic solar dish and shape and dimensions of the windows (32) of the oblong tubes (31) are set to allow electrical generation of DC power for at least two hours based on an approximately fifteen degree change in the angle of the Sun to the Earth over an hour period. The diameter of the parabola and the dimension of the windows (32) are made big enough to allow the focal point in each window to move across the window during that two-hour duration. Thus, the parabola and window dimensions are large enough so that a motor and a heliostat to automatically track the position of the Sun in the sky are not needed. Mounted within said obround thin walled tube (31) and behind said solar thermal trapping window (32) is the black body thermal absorber (33). Said black body solar light absorber (33) to trap heat energy is geometrically formed such that said solar thermal energy entering said solar thermal trapping window (32) impinges on and is absorbed by said black body solar light absorber (33). Said black body solar light absorber (33) is shaped geometrically by black color, surface roughness and geometric depth to maximize the absorption of said solar thermal energy, by means and methods well known to those skilled in the art. The black body solar light absorber (33) may consist of aluminum nitrate. Fixedly attached to the non solar thermal energy impinging side of said black body thermal absorber (33) is a multiplicity of Hoda multi-stacked TEG or other high efficiency multi-range temperature high efficiency TEG. As illustrated in FIG. 5, formed in rectangular and U shapes are multilayer thermal reflective layers (34). Each window (32) may be made up of one or more window sections.

Said multilayer thermal reflective layers (34) are composed of multilayers, in the preferred embodiment fifty, of alternating aluminum and fiberglass skim layers. Said aluminum layers have their most shinny side facing towards said black body solar light absorber (33) or said HODA TEG stacks (FIG. 6) in a configuration which forces said thermal energy to flow through said HODA TE generator stacks (FIG. 6) and not escape from said HODA TE generator stacks (FIG. 6) sides. Surrounding said black body thermal absorber (33) is an additional layer of multilayer thermal reflective layers (35), which in the preferred embodiment is twenty alternating layers, with said shinny side of said aluminum layers facing inward towards said black body solar light absorber (33) and said HODA TE generator stacks (FIG. 6). Said layer of multilayer thermal reflective layers (35) is in turn surrounded by a thermal isolation layer (36). Said thermal to electric generating components, thermal reflection, and thermal isolation layers are mounted inside an outer obround thin round tube (37). Thus said thermal to electric converter head section (FIG. 7) is formed as a unit body. Said positive (25) and negative (26) buss bars of said HODA TE generator stacks (FIG. 6) are connected to wires, composed of copper or other conductive material and covered with high temperature dielectric coatings of materials and designs well known to those skilled in the art, which lead from said HODA TE generator stacks (FIG. 6) down the inside of said outer obround thin round tube (36), through said head mount bracket (22), said extension tube (20), said head section mounting hollow shaft (18) to said collapsible base mount section.

Thus, the parabolic solar dish concentrates the solar photon energy through one or more thermal energy trapping windows (32) onto the black body heat absorber (33) and the black body heat absorber (33) are integrated with an insulated thermal storage mass to retain heat. Each thermal electric core in the stack is composed of a high density of P-type material and N-type material forming P-N junctions with one end of the P-type material and N- type material connected to an elevated temperature end thermally drawing heat from the black body heat absorber (33) and the other end of the P-type material and N-type material connected to a lowered temperature end thermally connected to a heat sink.

FIG. 8. illustrates an embodiment of the thermal to electric converter head section and its thermal dissipater to transfer thermal energy to the atmospheric air.

Referring to FIG. 8, after said thermal energy exits said HODA lower temperature TE device, (23), it transfers to a thermal dissipater (38) which transfers said thermal energy to the atmospheric air. Said thermal dissipater is composed of high thermal transfer material, such as aluminum or copper and is of a geometric form which allows air to pass through it to expose the maximum surface area to thermal transfer and is of types and designs well known to those skilled in the art. Said thermal dissipater (38) is mounted inside an obround outer flow induction shell (39). Mounted by said head mount bracket (22) is a thermal reflector cap (40) which has the dual function of protecting said thermal dissipater (38) from heating by direct sunlight and inducing a cross air flow which enhances said air flow coming through said thermal dissipater (38) and directs said cooling flow in a more vertical direction such that the rising warm air exits at the top of said solar direct thermal to electric converter head section so that it can dissipate into rising air or cross flow breezes more efficiently.

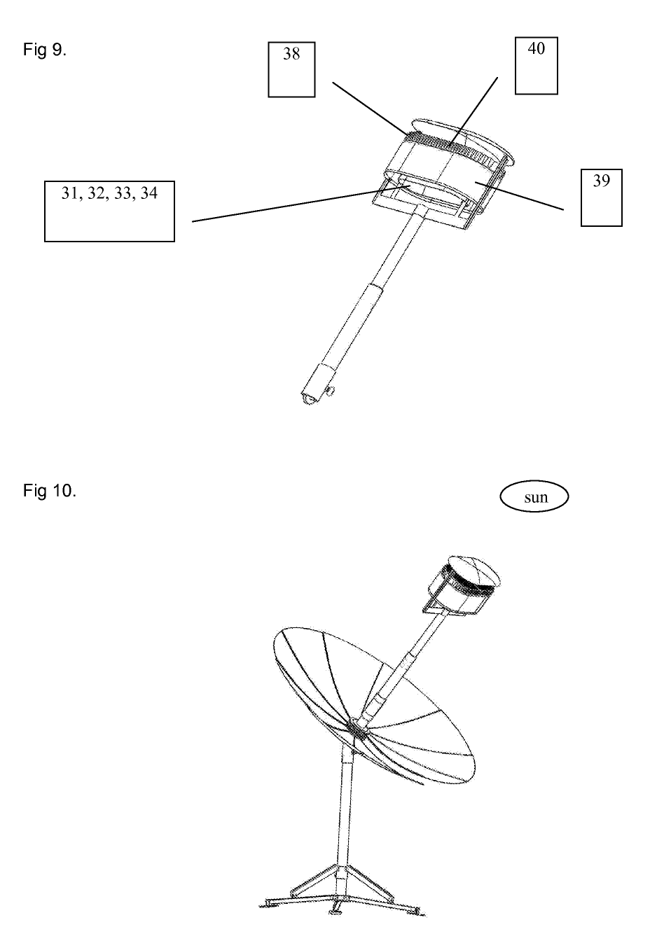

Referring to FIG. 9.

FIG. 9 illustrates the combination of said inner solar thermal section, said outer thermal dissipation section and said solar direct thermal to electric converter head section support. The combination of said thin walled tube (31), said solar thermal trapping window (32), said black body thermal absorber (33), said Hoda multi-stacked TEG (FIG. 6), said multilayer thermal reflectors (34) and said thermal dissipater (38) provides for the means to trap solar thermal energy and directly transmit the great majority of it directly through said multi-stacked TEG to produce the maximum efficient thermal energy to electrical energy conversion approaching forty percent efficiency.

In order to more efficiently reduce the temperature of said thermal energy, which has entered said thermal dissipater (38), to the ambient temperature an outer flow induction shell (39) is positioned around said thermal electric conversion head components and made of such material and geometry as to maximize the chimney effect of inducing air flow between said inner solar thermal section and said outer flow induction shell (39). Mounted above said thermal dissipater (38) is a thermal reflector cap (40) which protects said solar thermal electric generator head from incoming solar thermal energy and also acts as a cross flow induction path to ensure that said thermal energy is exited above said thermal electric generator head and will rise rapidly inducing additional flow from said ambient air.

Referring to FIG. 10.

FIG. 10 illustrates said solar direct thermal electric generator in its erected and generating state. Said solar direct thermal electric generator is facing towards the sun and generating electrical energy by the direct solar thermal electric process with said HODA multi-stacked TEG. Said three sections, base mount section, rotate-ably fold-able parabolic reflector section and thermal to electric converter head section are all connected and locked in place. Said base mount section positions said portable direct STEG facing the sun. Said rotate-ably fold-able parabolic reflector section reflects said sunlight and parabolic-ally concentrates it into said thermal to electric converter head section. As said solar thermal energy progresses through said HODA TE generator stacks, up to forty percent of said solar thermal energy is directly converted to direct current electrical energy. Said thermal dissipation components allow the unconverted solar thermal energy to dissipate into the ambient air. As long as the sun shines said solar direct thermal electric generator generates electricity.

In the preferred embodiment said solar direct thermal electric generator utilizes a rotate-ably fold-able parabolic reflector section of approximately one point three meters in diameter and said solar direct thermal electric generator produces approximately one kilowatt of electricity energy.

The hollow extension tube has rails for the thermal electric generation device housed in a head section to slide onto the rails. The length of the hollow extension tube and head section is approximately a focal length long based on a diameter of the parabola to maximize focused solar photon energy. The power cables from the bus bars are routed inside the hollow tubes of the base mount, the hollow extension tube that supports the multiple core stack, and thru the parabolic solar dish.

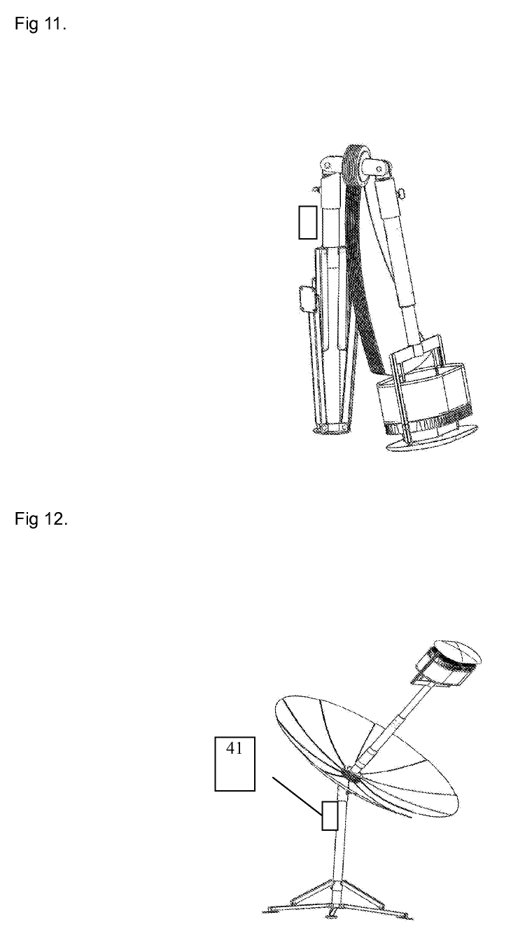

Referring to FIG. 11

FIG. 11 illustrates an embodiment of said solar direct thermal electric generator in its folded, transportable form.

Referring to FIG. 12

FIG. 12 illustrates an embodiment of said solar direct thermal electric generator with an attached DC to AC converter (41) module enabling said solar direct thermal electric generator to provide both DC current and AC current as long as the sun is shining.

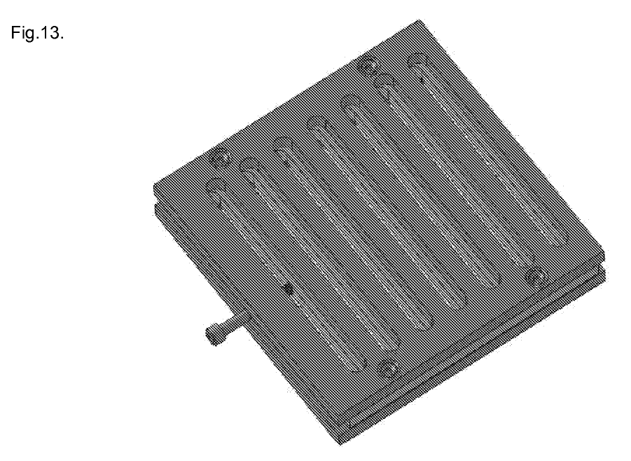

Referring to FIG. 13

FIG. 13 illustrates said thermal throttle comprised of alternating parts of the three sections in upper and lower two bodies that may slide in side from each other by offsetting certain distance. Each body comprised materials of non-thermal sides, thermal block (bars), and air-pocket opening (slots). A sliding mechanism and materials comprise of an array of bars and slots such that the thermal conduction range may be tuned from variable array overlap due to thermal block and air-pocket offset.

The multiple core stack contains the pairs of thermal electric materials supported by a thermal barrier of proper insulating material(s) so that the heat flows through the pairs of thermal electric materials only to generate the electricity.

We claim:

1. A portable electric generator powered by a solar thermal electric power source, comprising:
a parabolic solar dish to collect and reflectively concentrate solar photon energy into a heat-containment housing that contains some black body heat absorber to trap heat energy from the solar photon energy and that manages a thermal energy flow into a thermal electric generation device;
a thermally cascading stack of multiple thermal electric cores in the thermal electric generation device, where each of the thermal electric cores is composed of pairs of P-type and N-type materials optimized for the thermal electric generation in specific temperature ranges and exhibit the thermal electric effect at progressively lower temperatures;
bus bars coupled to the thermal electric generation device; and
a collapsible base mount having a hollow tube for a vertical support and connects to the parabolic solar dish to structurally support the parabolic solar dish.

2. The portable electric generator of claim 1, wherein the three sections 1) the collapsible base mount, 2) the parabolic solar dish, and 3) the thermally cascading stack of multiple thermal electric cores are fold-ably and electrically connected and the device can be folded for transport.

3. The portable electric generator of claim 1, wherein the parabolic solar dish concentrates the solar photon energy through one or more thermal energy trapping windows onto the black body heat absorber and the black body heat absorber are integrated with an insulated thermal storage mass to retain heat.

4. The portable electric generator of claim 1, wherein the multiple core stack contains the pairs of thermal electric materials supported by a thermal barrier of proper insulating material so that the heat flows through the pairs of thermal electric materials only to generate the electricity.

5. The portable electric generator of claim 1, wherein direct current (DC) electrical energy is drawn off each core stack of paired thermal electric material through positive and negative bus bars to contribute DC electricity to the bus bars to sum an efficiency of the heat energy to electrical generation conversion as each cascaded core stack generates DC electrical energy at progressively lower temperatures.

6. The portable electric generator of claim 1, wherein power cables from the bus bars are routed inside the hollow tubes of the base mount, an extension tube that supports the multiple core stack, and thru the parabolic solar dish.

7. The portable electric generator of claim 1, wherein individual thermal electric cores that are composed of pairs of P-type and N-type materials are optimized for highest thermal electric efficiency in the following temperature ranges and include but not limited to ones listed below:
900 deg C. P=SiGe
900 deg C. N=SiGe
600 deg C. P=SnTe or CeFe4Sb12
600 deg C. N=CoSb3
500 deg C. P=PbTe or TAGS or (Bix, Sbi-x) Te3
500 deg C. N=PbTe (500 C and below)
380 deg C. P=Zn4Sb3
380 deg C. N=PbTe (500 C and below)
160 deg C. P=Bi2Te3
160 deg C. N=Bi2Te3
where the thermal electric cores composed of said P type and N type materials are separated by thermal throttles which maintain a uniform thermal flow such that the thermal electric core materials are maintained close to their optimum efficiency temperature within the stack.

8. The portable electric generator of claim 1, wherein each thermal electric core in the stack is composed of a high density of P-type material and N-type material forming P-N junctions with one end of the P-type material and N- type material connected to an elevated temperature end thermally drawing heat from the black body heat absorber and the other end of the P-type material and N-type material connected to a lowered temperature end thermally connected to a heat sink.

9. The portable electric generator of claim 1, wherein the multiple core stack has three or more cascading temperature ranges with a different thermal electric material in each thermal electric core selected for an optimal temperature to generate electricity at each particular temperature range.

10. The portable electric generator of claim 1, wherein the black body heat absorber to trap heat energy is geometrically formed such that the solar energy entering a solar thermal trapping window impinges on and is absorbed by the black body heat absorber, and the black body heat absorber is shaped geometrically by black color, surface roughness and geometric depth to maximize the absorption of the solar energy and the black body heat absorber consists of aluminum nitrate.

11. The portable electric generator of claim 1, wherein the parabolic solar dish is rotate-ably connected to the collapsible base mount and has a fold-able parabolic reflector section.

12. The portable electric generator of claim 1, wherein the collapsible base mount has a locking collar that has an integral detent-locking pin, such that said slide locking collar can be slid up and down a hollow tube, in turn angularly altering a position of one or more support braces and support legs such that the collapsible base mount can be mounted upon nearly any surface.

13. The portable electric generator of claim 1, wherein the collapsible base mount has a sliding angle collar which can be slid up and rotated around the circumference of the hollow tube of the collapsible base mount and then fastened into place by a wing nut to position the second section at an optimum angle and rotation of the Sun, and attached to the top of said hollow tube is a pivot bracket which acts as the angularly variable attachment point for the parabolic solar dish and an extension tube.

14. The portable electric generator of claim 1, wherein a diameter of the parabolic solar dish and shape and dimensions of the windows of the oblong tubes are set to allow electrical generation of DC. power for at least two hours based on an approximately fifteen degree change in the angle of the Sun to the Earth over an hour period.

15. The portable electric generator of claim 1, wherein the parabolic solar dish includes a multiplicity of sectional parabolic solar reflectors that are shaped to form a parabola when expanded in a folded-out position and are grooved and has folds to interlock at the edges when the sections are rotated to a folded-up position.

16. The portable electric generator of claim 1, wherein the parabolic solar dish includes a multiplicity of sectional parabolic solar reflectors having holes in their attachment ends, formed in such a way as to allow the sectional parabolic solar reflectors to rotate in the spiral groove of a large threaded fitting on the collapsible base mount, and the sectional parabolic solar reflectors have folded edges which interlock with each other also when the sectional parabolic solar reflectors are rotated so as to create a full circular parabolic shape.

17. The portable electric generator of claim 1, wherein the parabolic solar dish includes a multiplicity of sectional parabolic solar reflectors that are foldable as a pin-latched fan-fold into alignment one section behind the next section and a parabolic surface that can snap into place to create a full circular parabolic shape.

18. The portable electric generator of claim 1, further comprising:
a hollow extension tube having rails for the thermal electric generation device housed in a head section to slide onto the rails, and the length of the hollow extension tube and head section are approximately a focal length long based on a diameter of the parabola to maximize focused solar photon energy.
